(19) United States
(12) Patent Application Publication
(10) Pub. No.: US 2015/0355678 A1
(43) Pub. Date: Dec. 10, 2015

(54) DOCKING STATION

(71) Applicant: Oxti Corporation, Taipei (TW)

(72) Inventor: Chih Feng HO, Taipei (TW)

(21) Appl. No.: 14/296,718

(22) Filed: Jun. 5, 2014

(51) Int. Cl. G06F 1/16; H05K 5/02

(52) U.S. Cl. CPC G06F 1/1632; H05K 5/0247; H05K 5/0204

(57) ABSTRACT

A docking station includes a housing having a number of connectors, and having two or more engaging elements and two or more engaging devices. The engaging elements are selected from cavities formed in the housing. The engaging devices are selected from projections formed on the housing. A receptacle includes two or more engaging members for engaging with the engaging elements of the housing and for detachably supporting the housing on the receptacle. One or more electric facilities include one or more engaging mechanisms for engaging with the engaging members of the receptacle and for detachably supporting the electric facilities on the receptacle.

### BACKGROUND OF THE INVENTION

1. Field of the Invention

The present invention relates to a docking station or port replicator, and more particularly to a docking station or port replicator including an organizing or docking structure for suitably receiving and storing or organizing the parts or elements and for connecting or coupling various electric or peripheral facilities together.

2. Description of the Prior Art

Various kinds of typical docking stations or port replicators have been developed and provided for connecting or coupling various electric or peripheral facilities together, such as the portable computers or notebooks, the personal computers or monitors, the speakers, the keyboards, the mouse facilities or the like to the ports or terminals or connectors of the docking stations or port replicators, and normally comprise a number of electric wires or cables for connecting or coupling the electric or peripheral facilities to the docking station or the like.

For example, U.S. Pat. No. 8,185,681 to Downing et al., U.S. Pat. No. 8,427,826 to Sullivan, U.S. Pat. No. 8,559,172 to Byrne, and U.S. Pat. No. 8,619,419 to Zimmermann et al., disclose several of the typical docking stations each comprising a docking station body or casing, and a number of electric wires or cables for connecting or coupling the electric or peripheral facilities to the docking station.

However, the electric wires or cables may not be suitably received and organized or stored in place, such as may not be suitably received and organized or stored in the docking station body or casing, and are normally randomly disposed or supported on the table, and may affect the working of the users.

The present invention has arisen to mitigate and/or obviate the afore-described disadvantages of the conventional docking stations or port replicators.

### SUMMARY OF THE INVENTION

The primary objective of the present invention is to provide a docking station including an organizing or docking structure for suitably receiving and storing or organizing the parts or elements and for connecting or coupling various electric or peripheral facilities together.

In accordance with one aspect of the invention, there is provided a docking station comprising a housing including a number of connectors provided thereon, and including at least two engaging elements provided therein, and including at least two engaging devices provided thereon for allowing two or more housings to be connected or coupled together.

The engaging elements are selected from holes or cavities formed in the housing. The cavities are preferably formed in a bottom portion of the housing. The engaging devices are selected from projections provided on the housing. The projections are preferably extended or protruded upwardly from an upper portion of the housing.

A receptacle may further be provided and includes at least two engaging members provided therein for engaging with the engaging elements of the housing and for stably supporting the housing on the receptacle and for preventing the housing from being disengaged from the receptacle.

The engaging members of the receptacle are preferably selected from protrusions extended upwardly from an upper portion of the receptacle for selectively engaging with the engaging elements of the housing. The receptacle includes a chamber formed therein for receiving various parts or elements, and includes at least one opening formed therein and communicating with the chamber of the receptacle for threading or engaging with the electric wires or cables or the like.

At least one electric facility may further be provided and includes at least one engaging mechanism provided therein for engaging with the engaging members of the receptacle and for solidly and stably anchoring and supporting the electric facility on the receptacle.

The engaging mechanism of the electric facility is preferably selected from a recess formed in a lower portion of the electric facility for engaging with the engaging members of the receptacle and for solidly and stably anchoring and supporting the electric facility on the receptacle. The electric facility is selected from a socket or the like.

At least one electric appliance may further be provided and includes at least one engaging mechanism provided therein for engaging with the engaging devices of the housing and for detachably or removably anchoring and supporting the electric appliance on the housing.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a perspective view of a docking station in accordance with the present invention, illustrating the operation of the docking station;

FIG. 2 is another perspective view of the docking station;

FIG. 3 is a partial perspective view of the docking station;

FIG. 4 is a further perspective view similar to FIG. 1, illustrating the other arrangement of the docking station; and

FIG. 5 is a still further perspective view similar to FIGS. 1 and 4, illustrating the further arrangement of the docking station.

### DETAILED DESCRIPTION OF THE PREFERRED EMBODIMENT

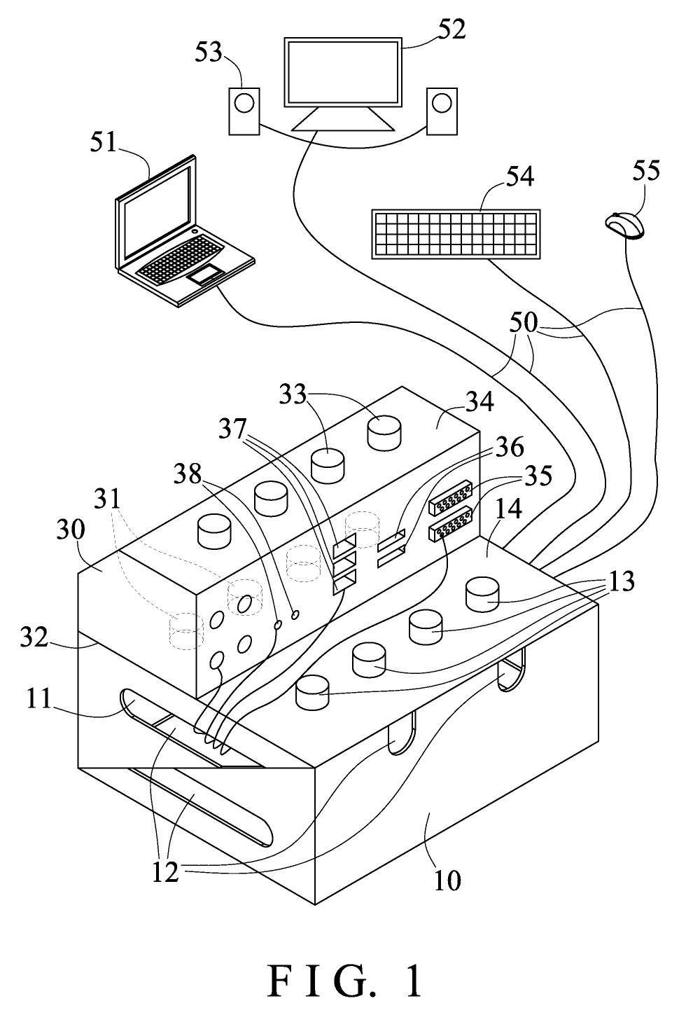

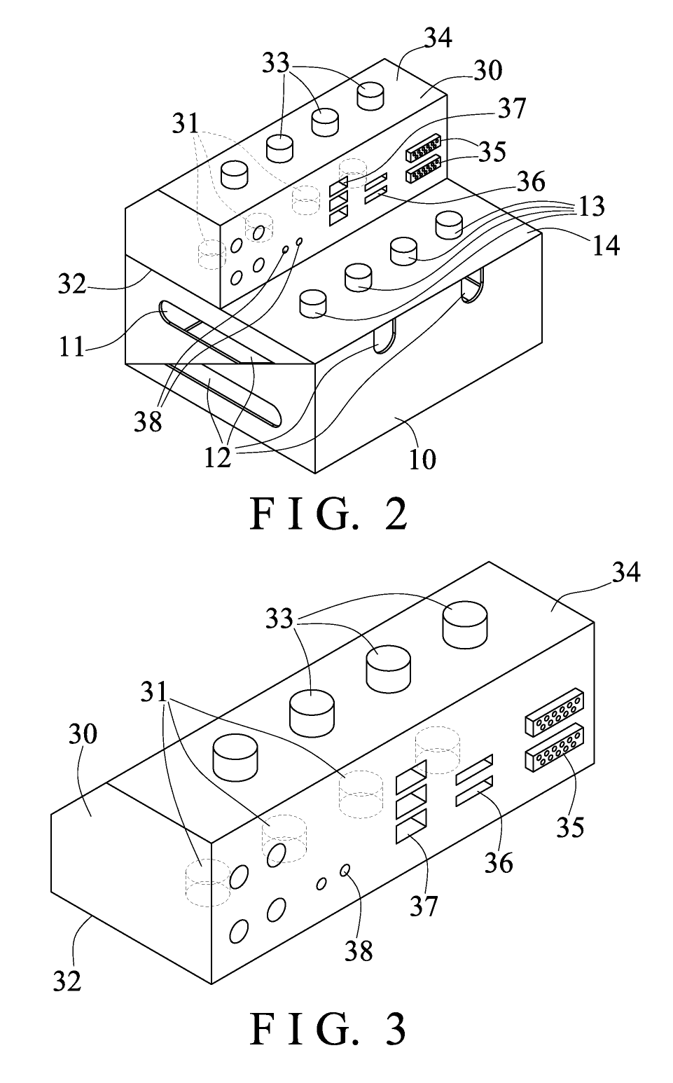

Referring to the drawings, and initially to FIGS. 1-3, a docking station in accordance with the present invention comprises an organizing or docking container or receptacle 10 including a compartment or chamber 11 formed therein for receiving or storing various kinds of parts or elements or appliances or facilities (not illustrated), and including one or more holes or orifices or openings 12 formed therein and communicating with the chamber 11 of the receptacle 10, and including one or more engaging members 13, such as bulges or pegs or protrusions 13 formed or provided therein, such as extended upwardly from the upper portion 14 of the receptacle 10.

The docking station further comprises a docking station body or housing 30 including one or more engaging elements 31, such as holes or recesses or cavities 31 formed or provided in the lower or bottom portion 32 of the housing 30 for selectively engaging with the engaging members or protrusions 13 of the receptacle 10 and f and for solidly and stably anchoring and supporting the electric facility on the receptacle.ably or selectively or removably anchoring or retaining or positioning the housing 30 on the receptacle 10 and for preventing the housing 30 from being disengaged or separated or detached from the receptacle 10. The housing 30 further includes one or more engaging elements or devices 33, such as bulges or pegs or protrusions or projections 33 formed or provided therein, such as extended upwardly from the upper portion 34 of the housing 30.

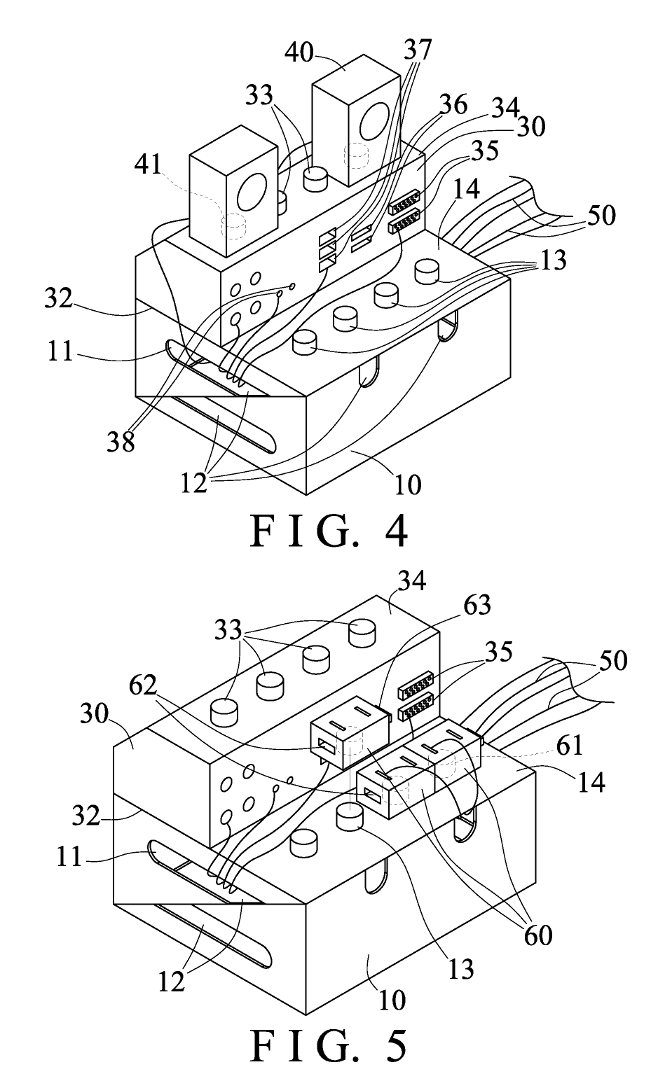

For example, as shown in FIG. 4, the other electric or peripheral facilities or appliances 40, such as the clocks, the video cameras, the decorations, the speakers 40 or the like each include one or more engaging mechanisms 41, such as holes or recesses or cavities or depressions 41 formed or provided in the lower or bottom portion of the electric facility or speaker 40 for selectively engaging with the engaging devices or projections 33 of the housing 30 and for detachably or selectively or removably anchoring or retaining or positioning the electric facility or speaker 40 on the housing 30 and for preventing the electric facility or speaker 40 from being disengaged or removed or separated from the housing 30.

As shown in FIG. 1, a number of electric wires or cables 50 may be provided for connecting or coupling various electric or peripheral appliances or facilities 51-55, such as the portable computer or notebook 51, the personal computer or monitor 52, the speaker 53, the keyboard 54, the mouse 55 or the like to the ports or terminals or connectors 35, 36, 37, 38 of the housing 30, and/or for connecting or coupling the electric or peripheral appliances or facilities 51-55 to the electric power supply or reservoir (not illustrated), and the electric cables 50 may be engaged through the openings 12 of the receptacle 10 and may be received and stored or organized in the chamber 11 of the receptacle 10, and for preventing the electric cables 50 from being randomly disposed or supported on the table, and thus for preventing the electric cables 50 from affecting the working of the users.

As shown in FIG. 5, the further electric or peripheral facilities or appliances 60, such as the plugs or sockets 60 each include one or more engaging mechanisms 61, such as holes or cavities or depressions or recesses 61 formed or provided in the lower or bottom portion of the electric facility or socket 60 for selectively engaging with the engaging members or protrusions 13 of the receptacle 10 and for detachably or selectively or removably anchoring or retaining or positioning the electric facility or socket 60 on the receptacle 10 and for preventing the electric facility or socket 60 from being disengaged or separated or detached from the receptacle 10 inadvertently, and the electric facility or socket 60 may be provided for electrically connecting or coupling to the electric or peripheral appliances or facilities 51-55 with the electric cables 50 or the like.

The electric facilities or sockets 60 each may include an engaging hole 62 formed therein, and each may include an engaging bulges or projections or protrusions or pegs or keys 63 formed or provided therein for selectively plugging or engaging with the engaging hole 62 of the other electric facilities or sockets 60 and thus for allowing the electric facilities or sockets 60 to be plugged or engaged with each other or to be connected or coupled together and to be solidly and stably supported on the receptacle 10. It is to be noted that the housing 30 includes one or more engaging elements or cavities 31 formed or provided therein for selectively engaging with the engaging members or protrusions 13 of the receptacle 10, and includes one or more engaging devices or projections 33 formed or provided thereon for selectively engaging with the engaging mechanisms or depressions 41 of the other electric or peripheral facilities or appliances 40 and for allowing the receptacle 10 and the housing 30 and the electric appliances 40 to be coupled together.

Accordingly, the docking station in accordance with the present invention includes an organizing or docking structure for suitably receiving and storing or organizing the parts or elements and for connecting or coupling various electric or peripheral facilities together.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A docking station comprising:
a housing including a plurality of connectors provided thereon, and including at least two engaging elements provided therein, and including at least two engaging devices provided thereon.

2. The docking station as claimed in claim 1, wherein said at least two engaging elements are selected from cavities formed in said housing.

3. The docking station as claimed in claim 2, wherein said cavities formed in a bottom portion of said housing.

4. The docking station as claimed in claim 1, wherein said at least two engaging devices are selected from projections provided on said housing.

5. The docking station as claimed in claim 4, wherein said projections are extended upwardly from an upper portion of said housing.

6. The docking station as claimed in claim 1 further comprising a receptacle including at least two engaging members provided therein for engaging with said at least two engaging elements of said housing.

7. The docking station as claimed in claim 6, wherein said at least two engaging members of said receptacle are selected from protrusions extended upwardly from an upper portion of said receptacle.

8. The docking station as claimed in claim 6 further comprising at least one electric facility having at least one engaging mechanism provided therein for engaging with said at least two engaging members of said receptacle.

9. The docking station as claimed in claim 8, wherein said at least one engaging mechanism of said at least one electric facility is selected from a recess formed in a lower portion of said electric facility for engaging with said at least two engaging members of said receptacle.

10. The docking station as claimed in claim 1 further comprising at least one electric appliance having at least one engaging mechanism provided therein for engaging with said at least two engaging devices of said housing and for detachably anchoring said at least one electric appliance on said housing.
